(19) United States
(12) Patent Application Publication
(10) Pub. No.: US 2007/0189077 A1
(43) Pub. Date: Aug. 16, 2007

(54) Semiconductor memory device

(75) Inventor: Kohji Kanamori, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/704,934

(22) Filed: Feb. 12, 2007

(30) Foreign Application Priority Data
Feb. 14, 2006 (JP) 2006-036667

(51) Int. Cl. G11C 16/04; G11C 11/34; G11C 16/06

(52) U.S. Cl. 365/185.24; 365/185.25; 365/185.19

(57) ABSTRACT

A programmable non-volatile semiconductor memory device having which a sufficient operational margin with miniaturized memory cells. The memory device includes select gates 3, arranged in a first region on a substrate 1, floating gates 6, arranged in a second region, neighboring to the first region, first diffusion regions 7, arranged in a third region neighboring to the second region, and control gates 11 arranged above the floating gates 6. It also includes a driving circuit 22 for controlling the voltages applied to the substrate 1, select gates 3, first diffusion areas 7 and the controlling gates 11. At the time of reprogramming, the driving circuit 22 controls the voltages for first control and second control. The first control sets a low threshold voltage state, inclusive of the depletion state, for the bits, connected to a selected one of the control gates 11. The second control sets a low threshold voltage state or a high threshold voltage state of a desired enhancement state from one bit to another.

### FIELD OF THE INVENTION

This invention relates to a semiconductor memory device and, more particularly, to a programmable non-volatile semiconductor memory device.

### BACKGROUND OF THE INVENTION

Among known semiconductor memory devices, there is a non-volatile semiconductor memory device shown for example in FIGS. 9 to 11 (see Patent Document 1 as a related art example). The non-volatile semiconductor memory device according to the related art example 1 includes first diffusion regions 107, select gates 103, second diffusion regions (121 in FIG. 9), floating gates 106 and control gates 111, in a memory cell array (see FIGS. 9 and 10).

The first diffusion regions 107 extend along one direction on the surface of a substrate 101 and are arrayed spaced apart from one another. The first diffusion regions 107 are used as local bit lines (LBs). Each select gate 103 (SG) is arrayed in a region on a substrate 101 between neighboring first diffusion regions 107, via insulating layer 102, and is extended along the direction of extension of the first diffusion regions 107. The second diffusion regions (121 of FIG. 9) are arranged on the surface of the substrate 101 in a layer below the select gate 103 outside the cell region and extends on both outer sides of the cell regions in a direction intersecting the select gates 103. The second diffusion region (121 of FIG. 9) is used as a common source (CS). The floating gate 106 (FG) is a storage node arrayed via insulating layer 102 in a region between the first diffusion region 107 and the select gate 103 via insulating layer 102 and the floating gates 106 (FG) are arrayed in the form of islands when seen from a direction normal to the major surface of the semiconductor memory device. The control gates 111 (CG) are arrayed via an insulating layer 108 above the floating gates 106 and the select gates 103 and are extended in a direction intersecting the select gates 103. The control gates 111 are used as word lines.

One of the first diffusion regions 107, lying on both sides of the select gate 103, the floating gate 106, the control gate 111 and the select gate 103 make up a first unit cell. The other of the first diffusion regions 107, lying on both sides of the select gate 103, the floating gate 106, the control gate 111 and the select gate 103 make up a second-unit cell. The first diffusion region 107 is shared by plural unit cells. With this non-volatile semiconductor memory device, a positive voltage is applied to the select gate 103 to generate an inversion layer 120 on a surface part of the substrate 101 lying below the select gate 103 in the cell region.

Voltages applied to the first diffusion regions 107, select gates 103, second diffusion regions 121, control gates 111 and the substrate 101 (wells 101a) are controlled by a driving circuit 122, which is a part of the peripheral circuit of the semiconductor memory device.

The select gate 103 includes a pair of select gate parts SG0, SG1 in an erase block 123 (see FIG. 11). The select gate parts SG0, SG1 are each formed as a comb when seen from a direction normal to the major surface of the semiconductor memory device. The comb teeth of the select gate part SG0 are arrayed at a preset interval between neighboring comb teeth of the select gate part SG1, whilst the comb teeth of the select gate part SG1 are arrayed at a preset interval between neighboring comb teeth of the select gate part SG0. The select gate parts SG0, SG1 are electrically connected to all of unit cells in the erase block 123. The erase block 123 is made up of a large number of unit cells, from the floating gate 106 of which electrons are drawn simultaneously when an erase operation is carried out. The erase operation will be explained subsequently. There are a plural number of the erase blocks 123 within one semiconductor memory device.

The operation of the non-volatile semiconductor memory device of the related art will now be described with reference to the drawings. FIGS. 12, 13, 14 and 15 depict schematic views for illustrating a readout operation, a write operation, a first erase operation and a second erase operation of the semiconductor memory device of the related art example 1, respectively.

The readout operation is explained mainly with reference to FIG. 12. If, in a state where no electrons are accumulated in the control gate 106 (erase state, with a threshold voltage being low), positive voltages are applied to the control gate 111, select gate 103 and to the second diffusion region (121 of FIG. 9), electrons e travel from the first diffusion region 107 through a channel directly below the floating gate 106 and through the inversion layer 120 formed below the select gate 103 to move to the second diffusion region (121 of FIG. 9). On the other hand, in a state where electrons are accumulated in the floating gate 106 (write state, with the threshold voltage being high), even if positive voltages are applied to the control gate 111, select gate 103 and to the second diffusion region (121 of FIG. 9), there is no flow of electrons e, in a manner not shown, because there is no channel below the floating gate 106. Readout may be by checking data (O/I, i.e.,) whether or not there is flow of electrons e.

The write operation is now described with reference to FIG. 13. In case a high positive voltage is applied to the control gate 111 and the first diffusion region 107, and a low positive voltage which allows the current of the order of 1 μA to flow through a memory cell of the select gate 103 is applied to the second diffusion region (121 of FIG. 9), the electrons e travel from the second diffusion region (121 of FIG. 9) through the inversion layer 120 formed underneath the select gate 103 to move to the first diffusion region 107. At this time, a fraction of the electrons e acquires a high energy due to an electrical field established in a boundary between the select gate 103 and the floating gate 106, so that part of the electrons 2 is injected through an insulating layer 105 (tunnel oxide film) below the floating gate 106 into the floating gate 106.

The first erase operation is now described with reference to FIG. 14. During the first erase operation, a high negative voltage is applied to the control gate 111, and a high positive voltage is applied to the substrate (well 101a). For example, a voltage V_{cg}=−9V is applied to the control gate 111, and a voltage V_{sub}=9V is applied to the substrate 101 (well 101a). The first diffusion region 107, select gate 103 and the second diffusion region (121 of FIG. 9) are open (OPEN). This draws electrons e from the floating gate 106 into the substrate (well 101a).

The second erase operation is now described with reference to FIG. 15. During the second erase operation, a high negative voltage is applied to the control gate 111, and a high positive voltage is applied to the select gate 103. For example, a voltage V_{cg}=−9V is applied to the control gate 111, and a voltage V_{sg}=3V is applied to the select gate 103. The substrate 101 (well 101a) and the second diffusion region (121 of FIG. 9) are open (OPEN). This draws electrons e from the floating gate 106 into the select gate 103.

Meanwhile, the erase operation is carried out in a lump in the erase block (123 of FIG. 11) and a write-back operation (write operation) is carried out for bits for which a threshold voltage Vt has become lower than the lower erasure limit value.

### [Patent Document 1]

Japanese Patent Kokai Publication No. JP-P2005-51227A

### SUMMARY OF THE DISCLOSURE

The disclosure of Patent Document 1 is herein incorporated by reference thereto.

However, if, with miniaturization of memory cells, variations of memory cell characteristics are increased, variations in the threshold voltage Vt on lump erasure are increased, so that there is fear that no sufficient operational margin can be secured. The operational margin is the difference between the threshold voltage Vt for the write state (see FIG. 16A) and that for the erase state (see FIG. 16C). In case the erase level is lowered to secure a sufficient operational margin, larger numbers of arbitrary memory cells in an erase block may be in a depletion state, with the threshold voltage Vt being lower than 0V (see FIG. 16B), with the result that the selective write-back operation cannot be performed to disable the operation. That is, if a memory cell on a selected bit line at a nonselected word line becomes a depletion state, an electric current flows through the cell in the depletion state during the write-back operation, resulting in failure of bit-line-voltage-rise even if a voltage is applied to the selected bit line. Thus, the write-back operation cannot be performed to the objective cell for write-back.

It is an object of the present invention to enable a sufficient operational margin even in case the memory cells are miniaturized.

In a first aspect of the present invention, there is provided a semiconductor memory device including a plurality of storage nodes provided on a substrate, a plurality of control gates arranged on the storage nodes, and a driving circuit that controls voltages applied to the substrate and the control gates. The driving circuit exercises a first control and a second control, by controlling the voltages, at the time of a rewriting operation. The first control sets a low threshold voltage state, inclusive of a depletion state, for a bit, connected to a selected one of the control gates. The second control sets a low threshold voltage state or a high threshold voltage state of a desired enhancement state, per the bit.

In a second aspect, the semiconductor memory device further comprises: a plurality of select gates, each arranged in a second region adjacent to a first region where the storage nodes are arranged; the driving circuit controlling the voltages applied to the select gates.

In a third aspect, the semiconductor memory device further comprises: a plurality of local bit lines, each arranged in a third region adjacent to the first region where the storage nodes are arranged; the driving circuit controlling the voltage applied to the local bit line or lines.

In a fourth aspect, the driving circuit applies a negative voltage and a positive voltage to the control gate and to the substrate, respectively, at the time of the first control, to draw electrons from the storage node or nodes to said substrate.

In a fifth aspect, the driving circuit applies a negative voltage and a positive voltage to the control gate and to the select gate, respectively, at the time of the first control, to draw electrons from the storage node or nodes to said select gate or gates.

In a sixth aspect, the driving circuit controls the voltages, at the time of the second control, to inject electrons selectively into the storage node or nodes.

In a seventh aspect, the driving circuit applies the voltages as pulsed voltages two or more times, at the time of the second control, to carry out verification of the storage node or nodes for matching to a desired threshold voltage.

In an eighth aspect, the driving circuit performs the first control for one of the control gates in a predetermined block and subsequently performs the second control for the one control gate.

In a ninth aspect, the driving circuit performs the first control for all of the control gates in a predetermined block and subsequently performs the second control for an optional one of the control gates.

The meritorious effects of the present invention are summarized as follows.

According to the present invention, as defined in the aspects 1 to 9, it is possible to narrow down the low threshold voltage distribution to secure an operational margin to improve the operational reliability. The reason is that a depletion state is not set except for the cell or cells (bit or bits) of the selected control gate (word line) so that both the low threshold voltage state and the high threshold voltage state can be set as the threshold voltage is adjusted per bit by a bit-selectable electron injection system.

### BRIEF DESCRIPTION OF THE DRAWINGS

FIG. 1 is a partial plan view schematically showing the configuration of a semiconductor memory device according to a first example of the present invention.

FIG. 2 is a partial cross-sectional view, taken along line X-X′ of FIG. 1, schematically showing the configuration of a semiconductor memory device according to the first example of the present invention.

FIG. 3 is a partial cross-sectional view for illustrating a first example of the operation from an initial state to an L′ state of the semiconductor memory device according to the first example of the present invention.

FIG. 4 is a partial cross-sectional view for illustrating a second example of the operation from an initial state to an L′ state of the semiconductor memory device according to the first example of the present invention.

FIG. 5 is a partial cross-sectional view for illustrating a first example of the operation from an L′ state to an H/L state of the semiconductor memory device according to the first example of the present invention.

FIG. 6 is a partial cross-sectional view for illustrating a second example of the operation from an L′ state to an H/L state of the semiconductor memory device according to the first example of the present invention.

FIG. 7 is a partial cross-sectional view for illustrating an operation of verification of the semiconductor memory device according to the first example of the present invention.

FIGS. 8A, 8B and 8C are graphs showing an H state, an L′ state and an L state of the threshold voltage distribution in the memory cells of the semiconductor memory device according to the first example of the present invention.

FIG. 9 is a partial plan view schematically showing the configuration of the semiconductor memory device according to a related art example 1.

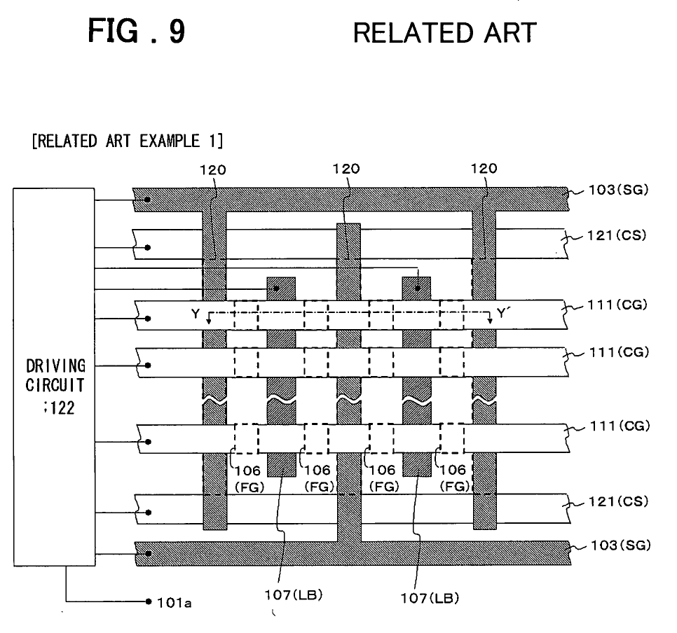

FIG. 10 is a partial cross-sectional view, taken along line Y-Y′ of FIG. 9, schematically showing the configuration of the semiconductor memory device according to the related art example 1.

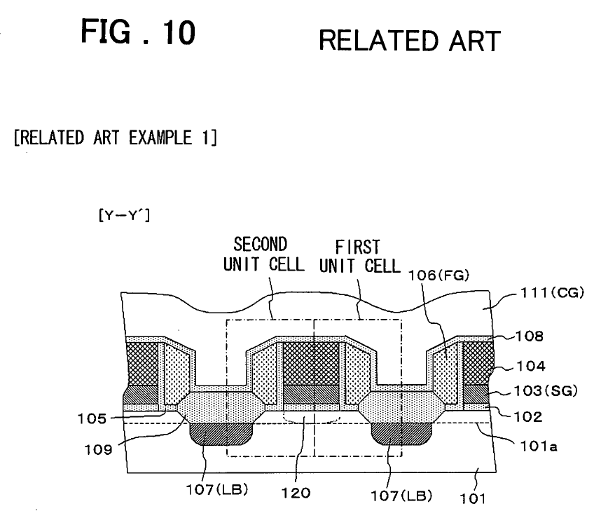

FIG. 11 is a partial plan view schematically showing the configuration of the select gate in an erase block of the semiconductor memory device according to the related art example 1.

FIG. 12 is a partial cross-sectional view for illustrating the readout operation of the semiconductor memory device according to the related art example 1, analyzed by the present invention.

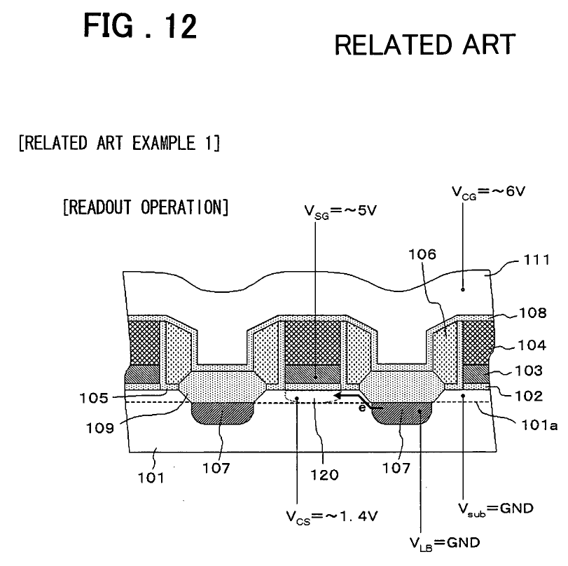

FIG. 13 is a partial cross-sectional view for illustrating a programming operation of the semiconductor memory device according to the related art example 1, analyzed by the present invention.

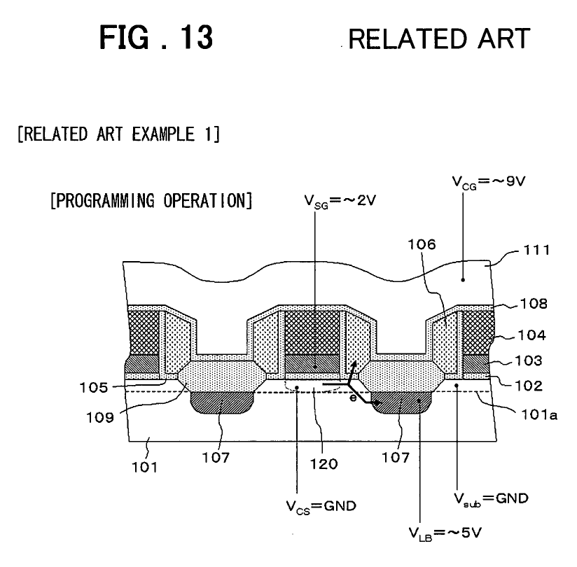

FIG. 14 is a partial cross-sectional view for illustrating a first erase operation of the semiconductor memory device according to the related art example 1, analyzed by the present invention.

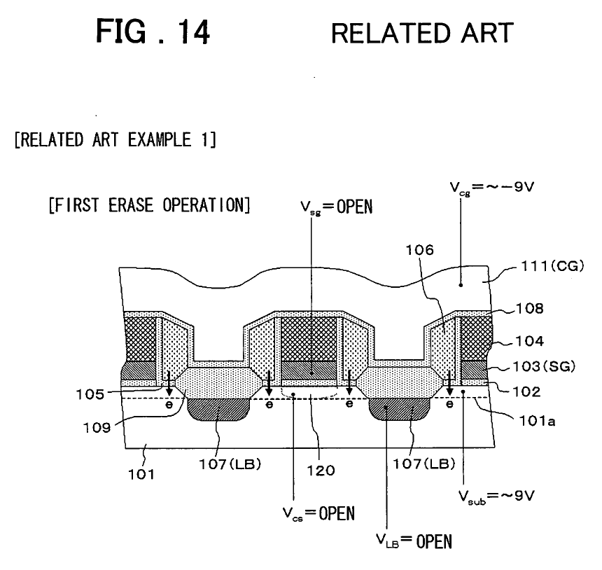

FIG. 15 is a partial cross-sectional view for illustrating a second erase operation of the semiconductor memory device according to the related art example 1, analyzed by the present invention.

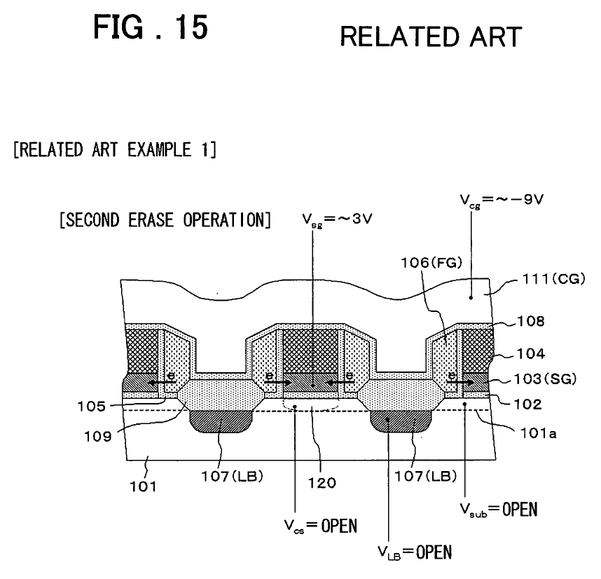

FIGS. 16A, 16B and 16C are graphs showing an H state, a depletion state and an L state of the threshold voltage distribution in a memory cell of the semiconductor memory device according to the related art example 1, analyzed by the present invention.

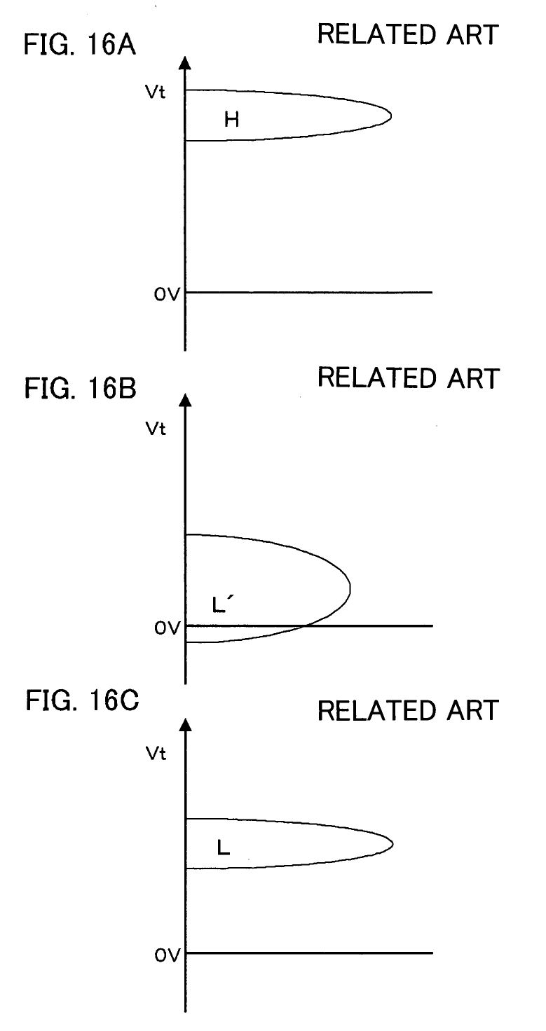

### PREFERRED MODES OF THE INVENTION

### FIRST EXAMPLE

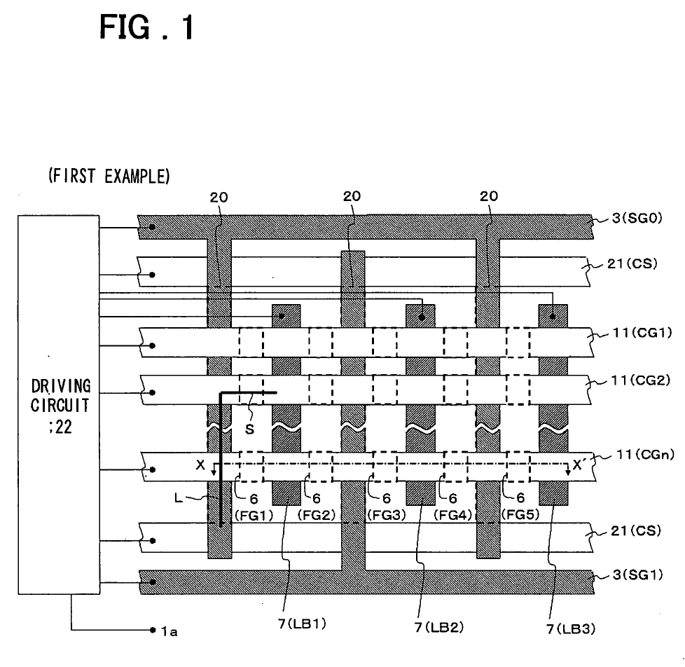

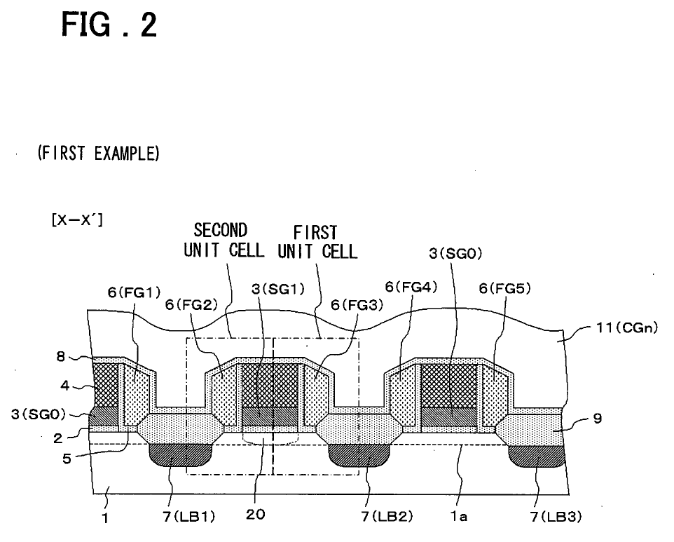

A semiconductor memory device according to a first example of the present invention will now be described with reference to the drawings. FIG. 1 depicts a partial plan view schematically showing the constitution of a semiconductor memory device according to the first example of the present invention. FIG. 2 is a partial cross-sectional view, taken along line X-X′ of FIG. 1, schematically showing the constitution of the semiconductor memory device according to the first example of the present invention.

The semiconductor memory device of the first example is a non-volatile semiconductor memory device for storing the 2-bit information per cell. The semiconductor memory device includes a substrate 1, an insulating film 2, select gates 3, an insulating film 4, an insulating film 5, floating gates 6, first diffusion regions 7, an insulating film 8, an insulating film 9, control gates 11 and second diffusion areas (21 of FIG. 1). A unit cell in the semiconductor memory device is made up of a first diffusion region 7, a floating gate 6, a control gate 11 and a select gate 3, as shown by a chain-dotted line in FIG. 2. A 2-bit cell in the semiconductor memory device is constructed by arraying two such unit cells in line symmetry, with the sole select gate being used in common. That is, the other unit cell of the 2-bit cell is similarly made up of a first diffusion region 7, a floating gate 6, a control gate 11 and a select gate 3, as shown in FIG. 2.

The substrate 1 is a P-type silicon substrate and has a well 1a below the select gate 3 and the floating gate 6. The well 1a is a p diffusion layer, and may also be termed a common-source diffusion area.

In the substrate 1, a channel which forms a path interconnecting the first diffusion region 7 and the second diffusion area 21 has a first path section L and a second path section S. As for the shape of the channel, as seen from above the substrate 1, the first path section L is extended from one of the second diffusion areas 21 along a direction as prescribed in connection with the planar configuration of the select gate 3, with the first path section being bent at a preset angle, such as a right angle, with respect to the aforementioned direction, to form the second path section S, so as to get to the first diffusion region 7. The channel part lying below the select gate 3 within the cell region of the first path section L becomes the inversion layer 20 when a positive voltage is applied to the select gate 3. In the second path section, the region below the floating gate 6 is also used as a channel region.

The insulating film 2 is provided between the select gate 3 and the substrate 1. The insulating film 2 may, for example, be a silicon oxide film, and is also termed a select gate insulating film.

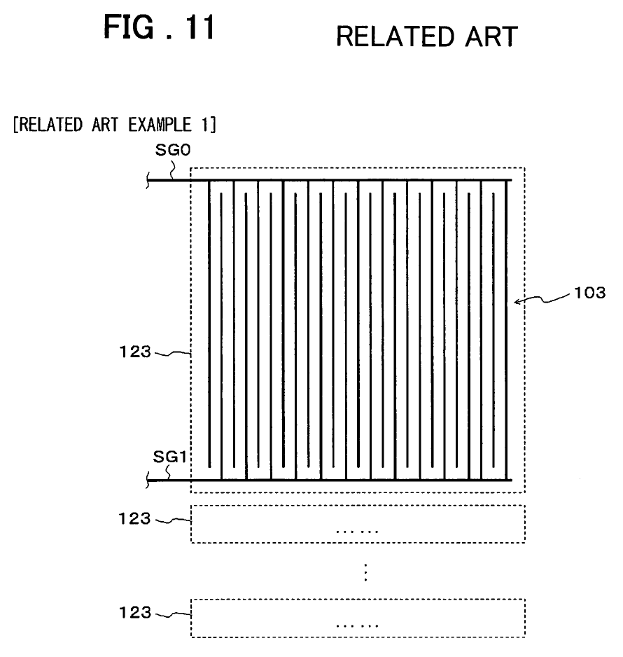

The select gate 3 is an electrically conductive film provided on the insulating film 2. For the select gate 3, polysilicon, for example, may be used. As in the related art example 1 (FIG. 11), the select gate 3 includes a pair of select gate parts SG0, SG1 within one erasure block 123. The select gate parts SG0, SG1 are shaped like comb teeth when seen along the direction perpendicular to the major surface of the semiconductor memory device. The comb teeth of the select gate part SG0 are arranged within the gaps of the comb teeth of the select gate part SG1, with a preset spacing in-between, while the comb teeth of the select gate part SG1 are arranged within the gaps of the comb teeth of the select gate part SG0, with a preset spacing in-between. The select gate parts SG0, SG1 are electrically connected to all of the unit cells in the erase block 123. Meanwhile, in case where the voltages applied to the select gates, arranged on both sides of the first diffusion region 7, when seen from the direction normal to the major surface of the semiconductor memory device, may be controlled to different values, the select gate may be provided in the divided form in three or more parts within one and the same erase block 123.

The insulating film 4 is provided on the select gate 3 (see FIG. 2). For the insulating film 4, a silicon oxide film or a silicon nitride film, for example, may be used.

The insulating film 5 is provided on sidewall sections of the insulating film 4, select gate 3 and the insulating film 2 and between the substrate 1 and the floating gate 6. For the insulating film 5, a silicon oxide film, for example, may be used (see FIG. 2). The insulating film 5 is also termed a “tunnel oxide film”.

The floating gate 6 is a storage node provided via the insulating film 5 on both sides of a select gate structure, made up of a layered assembly of the select gate 3 and the insulating film 4 (see FIG. 2). The floating gate 6 may be formed, e.g., of polysilicon. The floating gate 6 is formed like a sidewall section, when seen in a cross-section (see FIG. 2), while being formed like an island, when seen from the direction perpendicular to the planar surface (see FIG. 1). A trap type storage node may also be used in place of the floating gate 6.

The first diffusion region 7 is an n⁺ diffusion region, provided in a preset region (or regions) on the substrate 1, that is, in a region lying between the neighboring floating gates 6, and is arranged for extending along the direction of extension of the select gate 3, more precisely its comb tooth shaped parts (see FIGS. 1 and 2). The first diffusion region 7 becomes a drain region and a source region of a cell transistor, during rewriting (or overwriting) and readout, respectively, when the select gate 3 is taken into account as a part that makes up the cell transistor. The first diffusion region 7 is also termed a “local bit line” (LB).

The insulating film 8 is provided between the floating gate 6 and the control gate 11 (see FIG. 2). For the insulating film 8, an ONO film, made up of a silicon oxide film 8a, a silicon nitride film 8b and a silicon oxide film 8c, and which is high in insulating performance and in specific dielectric constant and lends itself to reducing the film thickness, may be used.

The insulating film 9 is provided between the insulating film 8 and the first diffusion region 7 (see FIG. 2). For the insulating film 9, a silicon oxide film, produced by thermal oxidation (thermal oxide film) or a silicon oxide film, formed by a CVD method, may be used.

The control gate 11 is extended in a direction crossing the longitudinal direction of the select gate 3, and which crosses the select gate 3 in an underpass (or overpass) formulation (see FIG. 1). At an intersection with the select gate 3, the control gate 11 contacts with an upper surface of the insulating film 8 provided as an upper layer of the select gate 3 (see FIG. 2). The control gate 11 is provided, via insulating film 5, floating gate 6 and insulating film 8, on both sides of a layered structure made up of the select gate 3 and the insulating film 8 (see FIG. 2). The control gate 11 is formed by an electrically conductive film of, for example, polysilicon. A high melting metal silicide, not shown, may be provided on the surface of the control gate 11 to provide for a low resistance. The control gate 11 operates as a word line.

The second diffusion area 21 is an n⁺ diffusion region and becomes a source/drain region of a cell transistor (see FIG. 1). The second diffusion area 21 extends in a direction perpendicular to the longitudinal direction of the select gate 3, in a region outside the cell region, and crosses the select gate 3 with an underpass. At an intersection with the select gate 3, the second diffusion area 21 is formed on a surface layer lying directly underneath the insulating film 2 provided as a lower layer of the select gate 3, in a manner not shown.

A driving circuit 22 is a part of a peripheral circuitry, and controls the voltages applied to the first diffusion region 7, select gate 3, control gate 11, substrate 1 (well 1a) and the second diffusion area 21, while verifying the threshold voltage of the memory cell. The voltage control by the driving circuit 22 differs from voltage control by the driving circuit of the non-volatile semiconductor memory device of the related art example 1, at least as to a writing/rewriting (overwriting or reprogramming) operation. The driving circuit 22 includes, e.g., a sense amplifier, a reference cell, a decoder and so forth. The voltage control and verification in the writing/rewriting operation of the driving circuit 22 will be explained subsequently.

It is noted that, with the exception of the driving circuit 22, the semiconductor memory device of the first example is similar in configuration to the non-volatile semiconductor memory device of the related art example 1. The semiconductor memory device of the first example may be fabricated by a method similar to the method for fabrication of the non-volatile semiconductor memory device of the related art example 1, insofar as the process from the formation of the well 1a up to the formation of the control gate 11 is concerned. The related disclosure of Patent Document 1 is here in incorporated by reference thereto.

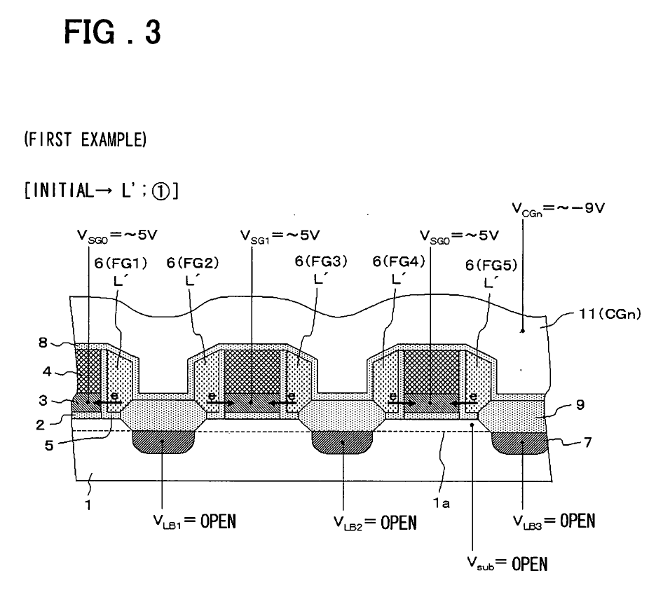

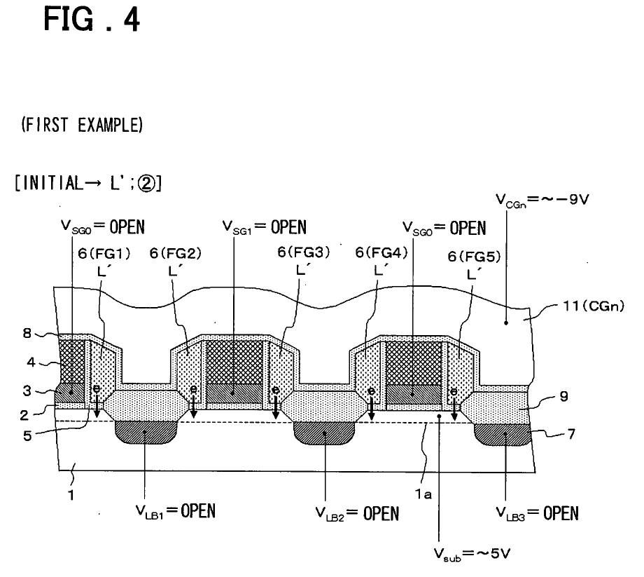

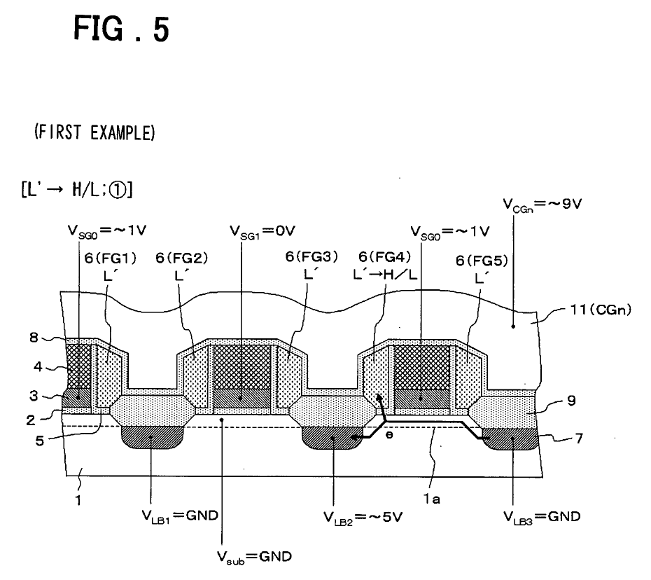

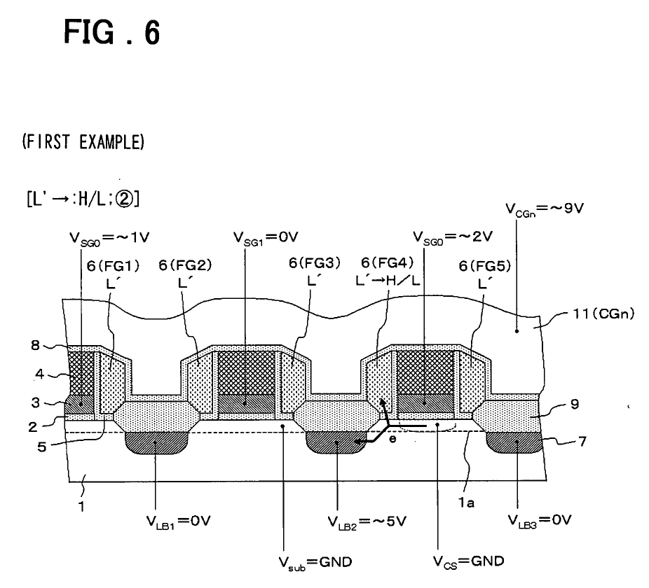

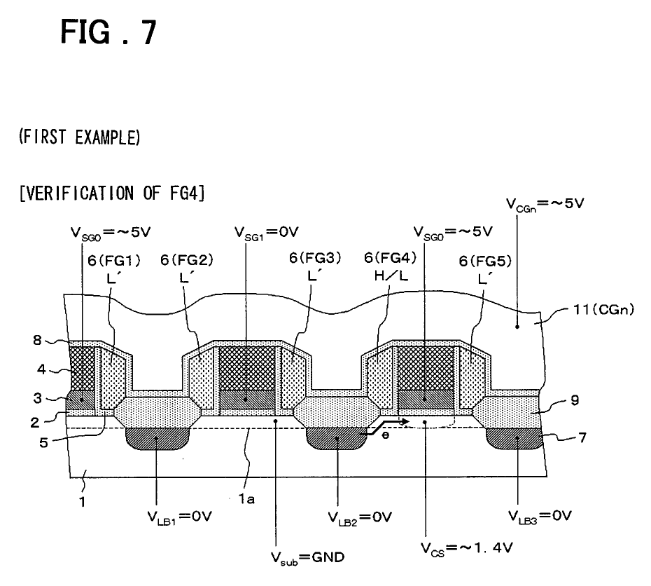

The operation of the semiconductor memory device according to the first example will now be described with reference to the drawings. FIG. 3 depicts a schematic cross-sectional view for illustrating a first example of the operation from an initial state to an L′ state of the semiconductor memory device according to the first example of the present invention. FIG. 4 depicts a schematic cross-sectional view for illustrating a second example of the operation from the initial state to the L′ state of the semiconductor memory device according to the first example of the present invention. FIG. 5 depicts a schematic cross-sectional view for illustrating a first example of the operation from the L′ state to the H/L state of the semiconductor memory device according to the first example of the present invention. FIG. 6 depicts a schematic cross-sectional view for illustrating a second example of the operation from the L′ state to the H/L state of the semiconductor memory device according to the first example of the present invention. FIG. 7 depicts a schematic cross-sectional view for illustrating the verifying operation of the semiconductor memory device according to the first example of the present invention. Meanwhile, L denotes a cell of a low threshold voltage state of an enhancement state (Vt>0), H denotes a cell of a high threshold value voltage state and L′ a low threshold voltage state inclusive of the depletion state (Vt≦0). The initial state may be a high threshold voltage state or a low threshold voltage state, unless the threshold voltage state of each cell is equal to or lower than the lower limit of the low threshold voltage, for example, a state of depletion.

The operation of reprogramming from the initial state to the L/H state will be described. Here, a case in which the initial state is the H, H state is taken for explanation.

Initially, the operation of drawing electrons from the floating gate 6 is carried out. Referring to FIG. 3, a negative voltage is applied to one of the control gates 11 in the erase block, whilst a positive voltage is applied to the select gate 6. For example, a voltage V_{CGn}=−9V is applied to the control gate 11 (CGn), and a voltage V_{SG0}=V_{SG1}=5V is applied to the select gates 6 (SG0, SG1), whilst the first diffusion regions 7 (LB1, LB2 and LB3) and the substrate 1 are open-circuited (OPEN). This draws electrons e from all of the floating gates 6, lying below the selected control gate 11 (CGn), to the select gate 3, through the tunnel oxide film 5 on the sidewall sections of the floating gates 6, and hence a low threshold voltage state, inclusive of the depletion state, is set in the cells associated with all of the floating gates 6 lying below the selected control gate 11n (CGn).

Meanwhile, a negative voltage and a high positive voltage may be applied to the sole control gate 11 in the erase block and to the substrate 1, respectively, as shown in FIG. 4, instead of performing voltage control shown in FIG. 3, at the time of electron drawing. For example, a voltage V_{cg}=−9V and a voltage V_{sub}=5V are applied to the control gate 11 (CGn) and the substrate 1, respectively, whilst the first diffusion region 7 (LB1, LB2 and LB3) and the select gates 3 are open-circuited (OPEN). This draws electrons e from all of the floating gates 6 lying below the selected control gate 11 (CGn) to the substrate 1, through the tunnel oxide film 5 lying below the floating gates 6, and hence a low threshold voltage state, inclusive of the depletion state, is set in the cells associated with all of the floating gates 6 lying below the selected control gate 11n (CGn).

After setting the cell to the depletion state, the operation of electron injection into the floating gates 6 is carried out. Referring to FIG. 5, a high positive voltage is applied to the control gate 11, e.g. CGn, associated with the cells in the depletion state, and to a preset first diffusion region 7, e.g. LB2. A low positive voltage which barely allows a current of 1 μA to flow through the memory cells is applied to a preset select gate 3, such as SG0, and the ground potential is applied to the first diffusion region 7 (LB3). For example, a voltage V_{CG}=9V is applied to the control gate 11 (CGn), and a voltage V_{LB2}=5V is applied to the first diffusion region 7 as the drain side (LB2). A threshold voltage or a voltage higher by a preset magnitude than the threshold voltage (1V) is applied to the select gate 3, and a ground voltage (GND=0V) is applied to the first diffusion region 7 (LB3), operating as a source side, and to the substrate 1. This causes electrons e to flow from the first diffusion region 7 (LB2) through a channel formed below the select gate 3 (SG0), without dependency on the state of data flowing through a channel below the floating gate 6 (FG5) and through a channel formed below the floating gate 6 (FG4) to flow into the first diffusion region 7 (LB2). At this time, part of the electrons e acquires a high energy due to an electrical field on the boundary between the select gate 3 (SG0) and the floating gate 6 (FG4) and hence is injected into the floating gate 6 (FG4) through the tunnel oxide film 5 below the floating gate 6 (FG4). This enables setting a low threshold voltage state or a high threshold voltage state in a desired enhancement state.

Meanwhile, the voltage control shown in FIG. 5 may not be performed during the operation of electron injection. In its stead, a high positive voltage may be applied to the control gate 11, associated with the cell in the depletion state, such as the control gate CGn, and to the preset first diffusion region 7 (LB2), as shown in FIG. 6. A preset low positive voltage, which barely allows the current of 1 μA to flow through the memory cells, may also be applied to the select gate 3, such as SG0. The ground potential may be applied to the second diffusion region (21 of FIG. 1). For example, a voltage V_{CG}=9V may be applied to the control gate 11 (CGn), and a voltage V_{SG0}=threshold voltage, (or a voltage higher by a preset value than the threshold voltage 1V), may be applied to the select gate 3 (SG0). A voltage V_{LB2}=5V may be applied to the first diffusion region 7 (LB2), operating as the drain side, whilst the ground voltage (GND=0V) may be applied to the second diffusion region 21 operating as the source side (buried diffusion layer) and to the substrate 1. This causes electrons e to flow from the second diffusion region (21 of FIG. 1) through the inversion layer 20 formed below the select gate 3 and through a channel formed below the floating gate 6 (FG4) to flow into the first diffusion region 7 (LB2). At this time, part of the electrons e acquires a high energy due to an electrical field on the boundary between the select gate 3 (SG0) and the floating gate 6 (FG4) and hence is injected into the floating gate 6 (FG4) through the tunnel oxide film 5 lying below the floating gate 6 (FG4). This enables setting a low threshold voltage state or a high threshold voltage state in a desired enhancement state.

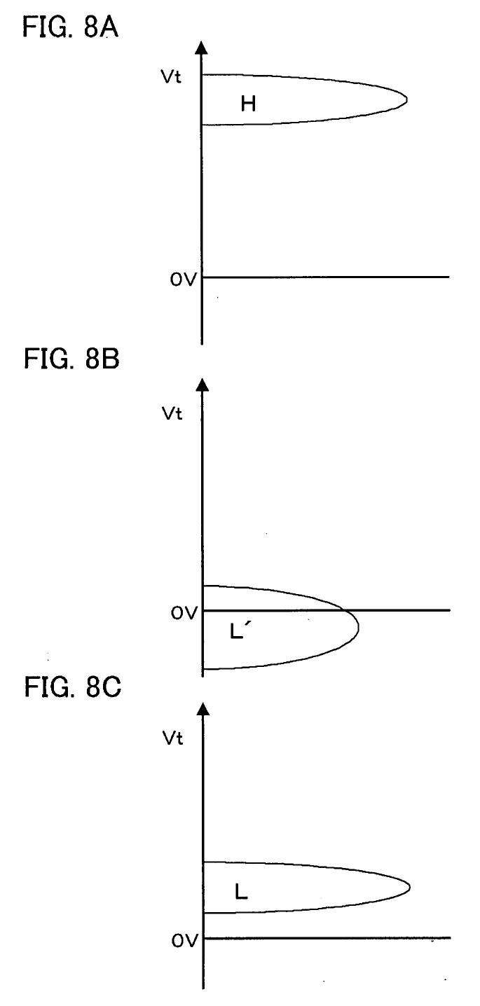

The voltage for electron injection is applied as two or more pulses, each bein1 ms g, for example, and the floating gate 6 (FG4) is verified for matching to a desired threshold voltage. The pulse application and verification are carried out alternately. Referring to FIG. 7, for verification, 5V is applied to the control gate 11 (CGn), as selected, while the non-selected control gates 11, such as CG1 or CG2, are at 0V. Also, 5V is applied to SG0, with the SG1 being at 0V. 1.4V is applied to the second diffusion region (common source CS 21 of FIG. 1), whilst 0V is applied to the first diffusion regions 7 (such as LB1, LB2 or LB3). The threshold voltage state of the floating gate FG4 and a voltage state in a reference cell, not shown, within the driving circuit (22 of FIG. 1), are compared to each other by a sense amplifier, not shown, within the driving circuit (22 of FIG. 1) connected to first diffusion regions 7 (such as LB1, LB2 or LB3). It is checked whether or not there flow electrons e below the floating gate FG4 in order to verify whether or not the threshold voltage of the floating gate FG3 has reached the target voltage. At a stage the electrons e cease to flow below the floating gate FG4, it is verified that the threshold voltage of the floating gate FG4 has reached the target voltage. The pulses cease to be applied at this time. By this operation, it is possible to set a low threshold voltage state or a high threshold voltage state for the floating gate FG4 in a desired enhancement state (see FIG. 8B). In addition, matching to any desired threshold voltage state may be achieved even if memory cell characteristics suffer from variations.

The operation for electron injection is subsequently carried out for other cells which are in depletion states and in which the operation of electron injection has not been carried out, in order to set a low threshold voltage state or a high threshold voltage state in a desired enhancement state. After the setting for all cells pertinent to the preset control gate 11, such as CGn, has come to a close, the operation of electron drawing (extraction) or electron injection is carried out for another control gate, such as CGn+1.

The above operations may be completed from one word in a block to another. It is also possible to carry out the operation of electron injection after the end of the operation of electron extraction for all cells in the control gates 11 which is carried out from one control gate 11 to another.

With the first example, it is possible to narrow the low threshold voltage distribution and to secure the operational margin to improve the operational reliability. The reason is that no depletion state is set in other than the cells (bits) of the selected control gate 11 (word line) so that both the low threshold voltage state and the high threshold voltage state may be set by adjusting the threshold voltage bit-by-bit in accordance with a bit-selectable electron injection system.

In the first example, there are provided select gates and local bit lines. It is however possible to dispense with the select gates or the local bit lines in case the operation of electron drawing (extraction) may be carried out on the word line basis and the operation may be carried out on the bit basis.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor memory device comprising:
a plurality of storage nodes provided on a substrate;
a plurality of control gates arranged above said storage nodes; and
a driving circuit that controls voltages applied to said substrate and said control gates;
said driving circuit exercising a first control and a second control, by controlling said voltages, at the time of rewriting operation; said first control setting a low threshold voltage state, inclusive of a depletion state, for bits, connected to a selected one of said control gates; said second control setting a low threshold voltage state or a high threshold voltage state of a desired enhancement state, per said bit.

2. The semiconductor memory device according to claim 1, further comprising:
a plurality of select gates, each arranged in a second region adjacent to a first region where said storage nodes are arranged;
said driving circuit controlling the voltages applied to said select gates.

3. The semiconductor memory device according to claim 1, further comprising:
a plurality of local bit lines, each arranged in a third region adjacent to said first region where said storage nodes are arranged;
said driving circuit controlling the voltage applied to said local bit line or lines.

4. The semiconductor memory device according to claim 2, further comprising:
a plurality of local bit lines, each arranged in a third region adjacent to said first region where said storage nodes are arranged;
said driving circuit controlling the voltage applied to said local bit line or lines.

5. The semiconductor memory device according to claim 1 wherein
said driving circuit applies a negative voltage and a positive voltage to said control gate and to said substrate, respectively, at the time of said first control, to draw electrons from said storage node or nodes to said substrate.

6. The semiconductor memory device according to claim 2 wherein
said driving circuit applies a negative voltage and a positive voltage to said control gate and to said substrate, respectively, at the time of said first control, to draw electrons from said storage node or nodes to said substrate.

7. The semiconductor memory device according to claim 3 wherein
said driving circuit applies a negative voltage and a positive voltage to said control gate and to said substrate, respectively, at the time of said first control, to draw electrons from said storage node or nodes to said substrate.

8. The semiconductor memory device according to claim 2 wherein
said driving circuit applies a negative voltage and a positive voltage to said control gate and to said select gate, respectively, at the time of said first control, to draw electrons from said storage node or nodes to said select gate or gates.

9. The semiconductor memory device according to claim 3 wherein
said driving circuit applies a negative voltage and a positive voltage to said control gate and to said select gate, respectively, at the time of said first control, to draw electrons from said storage node or nodes to said select gate or gates.

10. The semiconductor memory device according to claim 5 wherein
said driving circuit controls the voltages, at the time of said second control, to inject electrons selectively into said storage node or nodes.

11. The semiconductor memory device according to claim 8 wherein
said driving circuit controls the voltages, at the time of said second control, to inject electrons selectively into said storage node or nodes.

12. The semiconductor memory device according to claim 10 wherein
said driving circuit applies the voltages as pulsed voltages two or more times, at the time of said second control, to carry out verification of said storage node or nodes for matching to a desired threshold voltage.

13. The semiconductor memory device according to claim 11 wherein
said driving circuit applies the voltages as pulsed voltages two or more times, at the time of said second control, to carry out verification of said storage node or nodes for matching to a desired threshold voltage.

14. The semiconductor memory device according to claim 1 wherein
said driving circuit performs said first control for one of said control gates in a predetermined block and subsequently performs said second control for said one control gate.

15. The semiconductor memory device according to claim 2 wherein
said driving circuit performs said first control for one of said control gates in a predetermined block and subsequently performs said second control for said one control gate.

16. The semiconductor memory device according to claim 3 wherein
said driving circuit performs said first control for one of said control gates in a predetermined block and subsequently performs said second control for said one control gate.

17. The semiconductor memory device according to claim 1 wherein
said driving circuit performs said first control for all of said control gates in a predetermined block and subsequently performs said second control for an optional one of said control gates.

18. The semiconductor memory device according to claim 2 wherein
said driving circuit performs said first control for all of said control gates in a predetermined block and subsequently performs said second control for an optional one of said control gates.

19. The semiconductor memory device according to claim 3 wherein
said driving circuit performs said first control for all of said control gates in a predetermined block and subsequently performs said second control for an optional one of said control gates.

20. The semiconductor memory device according to claim 14 wherein
said driving circuit performs said first control for all of said control gates in a predetermined block and subsequently performs said second control for an optional one of said control gates.
